(19) United States
(12) Patent Application Publication
(10) Pub. No.: US 2024/0355800 A1
(43) Pub. Date: Oct. 24, 2024

(54) OPTOELECTRONIC COMPONENT, LIGHTING UNIT AND METHOD OF MANUFACTURING AN OPTOELECTRONIC COMPONENT

(71) Applicant: ams-OSRAM International GmbH, Regensburg (DE)

(72) Inventor: Andreas Waldschik, Wolmirstedt (DE)

(21) Appl. No.: 18/684,565

(22) PCT Filed: Sep. 1, 2022
(86) PCT No.: PCT/EP2022/074295

§ 371 Date: Feb. 16, 2024

(30) Foreign Application Priority Data
Sep. 15, 2021 (DE) 10 2021 123 819.6

(51) Int. Cl. H01L 25/16; H01L 25/075; H01L 33/00; H01L 33/48; H01L 33/56; H01L 33/60; H01L 33/62; H05B 45/18

(52) U.S. Cl. CPC H01L 25/167; H01L 25/0753; H01L 33/005; H01L 33/486; H01L 33/56; H01L 33/60; H01L 33/62; H01L 2933/005; H01L 2933/0058; H01L 2933/0066; H05B 45/18

(57) ABSTRACT

In an embodiment an optoelectronic component includes a lead frame with a plurality of contacts, a circuit chip having a driver circuit, a bottom side facing the lead frame and a top side facing away from the lead frame, at least one radiation-emitting semiconductor chip arranged on the top side of the circuit chip, a redistribution layer arranged between the circuit chip and the radiation-emitting semiconductor chip for electrically contacting the driver circuit and the radiation-emitting semiconductor chip, and a housing body fastened to the lead frame, the housing body enclosing the circuit chip and having at least one recess above the circuit chip, in which the at least one radiation-emitting semiconductor chip is arranged, wherein terminals of the radiation-emitting semiconductor chip are electrically connected to the redistribution layer via bumps, and wherein the redistribution layer is electrically connected to the contacts of the lead frame via wire bonds.

### CROSS-REFERENCE TO RELATED APPLICATIONS

This patent application is a national phase filing under section 371 of PCT/EP2022/074295, filed Sep. 1, 2022, which claims the priority of German patent application 102021123819.6, filed Sep. 15, 2021, each of which is incorporated herein by reference in its entirety.

### TECHNICAL FIELD

Lighting units can be formed using semiconductor chips. In particular, light-emitting diodes (LEDs) or, respectively, the light emitted by the diodes can be used to cover a wide color space. An integrated circuit (IC) with a driver circuit is advantageous for controlling the LEDs in order to supply the LEDs with sufficient power. Another function of the circuit chip can be to ensure color homogeneity and color stability of the emitted light. The brightness of red LEDs in particular can be very temperature-sensitive, which means that temperature compensation may be necessary.

### BACKGROUND

If the LEDs are mounted on a lead frame at a certain distance from the circuit chip, there may be materials with poor thermal conductivity between the IC and the LEDs, which can severely restrict the thermal coupling between the circuit chip and the LEDs. The color location correction is therefore subject to a correspondingly high degree of inaccuracy. Furthermore, the component is correspondingly large due to the lateral arrangement of the LED and IC.

### SUMMARY

Embodiments provide an optoelectronic component having an efficient arrangement. Further embodiments provide a lighting unit comprising a plurality of such optoelectronic components. Yet other embodiments provide a method for manufacturing an optoelectronic component.

Embodiments of the present disclosure are based on the idea of arranging a circuit chip and radiation-emitting semiconductor chips in a stacked manner to improve thermal coupling between both chips and to achieve a minimum component size.

Here and hereinafter, “radiation” or “light” may in particular denote electromagnetic radiation having one or more wavelengths or wavelength ranges. In particular, light or radiation described herein and hereinafter may comprise or be visible light.

According to at least one embodiment, an optoelectronic component comprises a lead frame with a plurality of contacts. The contacts are designed as electrical connections (“pins”) and are electrically insulated from each other. The lead frame can comprise a base body that can also serve as a temperature sink or heat sink. The contacts can be arranged in lateral directions around the base body. Lateral directions run parallel to a main plane of extension of the lead frame. The lead frame comprises a rear side and a front side. The lead frame and in particular the contacts of the lead frame comprise a bondable surface on the front side in order to be able to attach wire connections to it. The rear side of the lead frame can be attached to a circuit board by bonding and/or soldering, for example. For this purpose, the contacts can comprise solder control structures to ensure visual inspection of the soldering points.

According to at least one embodiment, the optoelectronic component comprises a circuit chip. The circuit chip comprises a bottom side facing the lead frame and a top side facing away from the lead frame. Furthermore, the circuit chip comprises a driver circuit.

This means that the circuit chip is arranged above the lead frame in a transverse direction. The transverse direction is perpendicular to the main plane of extension of the lead frame. A main plane of extension of the circuit chip runs essentially parallel or parallel to the main plane of extension of the lead frame. The bottom side of the circuit chip is attached to the front side of the lead frame and, in particular, to the base body of the lead frame. The contacts of the lead frame are not covered by the circuit chip. The circuit chip can, for example, be attached to the lead frame by means of an adhesive layer. Preferably, the adhesive layer is a thermally conductive adhesive layer. The circuit chip can consist of semiconductor materials and be manufactured using CMOS technology, for example. In addition to the driver circuit, the circuit chip can comprise further circuit components. For example, the circuit chip also comprises a temperature sensor, a communication unit and/or a memory element. The circuit chip can enable calibration of the LEDs, with calibration data being stored in the chip's programmable memory element. The driver circuit of the circuit chip is intended and configured to provide a drive current for operating a semiconductor chip described below.

According to at least one embodiment, the optoelectronic component comprises at least one radiation-emitting semiconductor chip. The radiation-emitting semiconductor chip is arranged on the top side of the circuit chip.

This means that in the transverse direction, the radiation-emitting semiconductor chip, hereinafter referred to as the semiconductor chip, is arranged above the circuit chip. A main plane of extension of the semiconductor chip runs essentially parallel or parallel to the main plane of extension of the circuit chip. The lead frame, the circuit chip and the semiconductor chip are arranged on top of each other and form a stack. The semiconductor chip can be attached to the circuit chip by means of a further adhesive layer, whereby the further adhesive layer can be formed by a thermally conductive adhesive layer. The optoelectronic component can comprise a plurality of semiconductor chips, each of which is arranged on the top side of the circuit chip. In particular, the optoelectronic component comprises semiconductor chips that emit light of different wavelengths during operation. For example, a first semiconductor chip emits light in the red wavelength range, a second semiconductor chip emits light in the green wavelength range and a third semiconductor chip emits light in the blue wavelength range. It is also possible for another semiconductor chip to emit light in a non-visible wavelength range, for example in the infrared or ultraviolet range.

According to at least one embodiment, the optoelectronic component comprises a redistribution layer for electrical contacting of the driver circuit and the radiation-emitting semiconductor chip, which is arranged between the circuit chip and the radiation-emitting semiconductor chip.

This means that the redistribution layer is arranged on the top side of the circuit chip, and the semiconductor chip is arranged on the redistribution layer. The redistribution layer is electrically connected to electronic components of the circuit chip, in particular the driver circuit. This can mean that the redistribution layer is electrically connected to conductor tracks within the circuit chip.

The radiation-emitting semiconductor chip comprises terminals that are electrically connected to the redistribution layer, in particular via bumps.

In particular, the connections of the semiconductor chip can comprise an anode and a cathode connection for an LED arranged in the semiconductor chip. The connections of the semiconductor chip can be arranged on a side of the semiconductor chip that is opposite the radiation-emitting side. In particular, this can mean that the semiconductor chip is arranged on the redistribution layer by means of flip chip mounting. The bumps can be formed, for example, by solder bumps, by the contacts of the semiconductor chip, by so-called stud bumps or by electrically conducting adhesives.

According to at least one embodiment, the optoelectronic component comprises wire bonds. The redistribution layer is electrically connected to the contacts of the lead frame via the wire bonds. The wire bonds can be made of gold, for example.

By applying an application-specific redistribution layer to the circuit chip contacting surfaces are created for the semiconductor chip. By mounting the semiconductor chip directly on the top of the circuit chip, the best possible thermal coupling is achieved, as the heat emitted by the semiconductor chip is transported directly through the circuit chip to the heat sink. The circuit chip and the semiconductor chip are thermally coupled by the arrangement described. The materials used can be designed thermally conductive so that the heat path between the semiconductor chip and the circuit chip can be reduced to less than 10 μm.

Compared to a lateral arrangement of the semiconductor chip next to the circuit chip, stacking requires less lateral space, which results in a significant reduction in component size. The use of bumps (i.e. flip-chip mounting) also eliminates the need for wire connections to the semiconductor chip, which offers further cost reduction potential. For example, the component size can be reduced to less than 2.4×1.9 mm².

According to at least one embodiment, an optoelectronic component comprises a lead frame with a plurality of contacts, a circuit chip comprising a driver circuit and comprising a bottom side facing the lead frame and a top side facing away from the lead frame, at least one radiation-emitting semiconductor chip arranged on the top side of the circuit chip, a redistribution layer arranged between the circuit chip and the radiation-emitting semiconductor chip for electrically contacting the driver circuit and the radiation-emitting semiconductor chip, terminals of the radiation-emitting semiconductor chip being electrically connected to the redistribution layer via bumps and the redistribution layer being electrically connected to the contacts of the lead frame via wire bonds.

According to at least one further embodiment, the at least one radiation-emitting semiconductor chip comprises a light-emitting diode.

For example, the light-emitting diode (LED) or lighting diode is a gallium nitride (GaN)-based LED grown on a sapphire substrate. The LED may comprise a first n-doped semiconductor layer and a second p-doped semiconductor layer, forming a pn junction. The sapphire substrate may be provided to increase the light outcoupling efficiency of the diode. Silicon-based diodes are also possible. Preferably, the LED is a flip-chip LED, i.e. an LED whose terminals are arranged on a side opposite the light-emitting side.

A light-emitting diode can comprise small dimensions. Due to its small size, a high degree of flexibility can be achieved so that the radiation source can be adapted to the system. The small size also makes it possible to arrange individual LEDs, or semiconductor chips, in arrays and pixels. Furthermore, LEDs comprise a low operating temperature and allow fast switching cycles. The emitted wavelength of LEDs can be specifically adjusted. LEDs comprise high mechanical stability and a long service life. The emitted light intensity of LEDs can be adjusted in a range of approx. 1-100% of the nominal power by varying the driver current.

According to at least one further embodiment, the at least one radiation-emitting semiconductor chip comprises a first semiconductor chip which, in operation, emits light in the red wavelength range. Alternatively or additionally, the at least one radiation-emitting semiconductor chip comprises a second semiconductor chip which, in operation, emits light in the green wavelength range. Alternatively or additionally, the at least one radiation-emitting semiconductor chip comprises a third semiconductor chip which, in operation, emits light in the blue wavelength range.

This can mean that a total of three semiconductor chips are arranged on the top of the circuit chip. According to at least one further embodiment, the optoelectronic component comprises at least one further semiconductor chip that emits light in a further wavelength range. The semiconductor chips can be arranged linearly, i.e. in a row, on the top side of the circuit chip. It is also possible for the semiconductor chips to be arranged in a different arrangement to one another, for example in a triangular arrangement or a matrix arrangement.

By arranging several semiconductor chips that emit light in different wavelength ranges during operation, a broad color spectrum can be covered. In particular, an even broader color spectrum can be achieved by mixing the light emitted by the semiconductor chips.

According to at least one further embodiment, a radiation direction of the at least one radiation-emitting semiconductor chip comprises a transverse direction that is perpendicular to the main plane of extension of the lead frame.

This can mean that the at least one semiconductor chip emits light essentially in a direction facing away from the lead frame. The optoelectronic component can therefore be designed as a so-called top-looker. However, the emission direction can also contain lateral directional components. Advantageously, the direction of emission includes directions in which the emitted light is not prevented from propagating by the optoelectronic component. This is made possible in particular by the fact that terminals of the semiconductor chip are arranged on a side of the semiconductor chip that is opposite the radiation-emitting side and that these terminals are connected to the redistribution layer by means of flip-chip mounting.

According to at least one further embodiment, the optoelectronic component also comprises a housing body attached to the lead frame. The housing body is designed in such a way that it encloses the circuit chip. The housing body comprises at least one recess above the circuit chip, in which the at least one radiation-emitting semiconductor chip is arranged.

The housing body can comprise a suitable plastic material with which the circuit chip is surrounded, for example overmolded. Preferably, the housing body comprises a white encapsulation material in order to comprise reflective/reflecting properties for the emitted light. The housing body may comprise an epoxy or silicone-based material. The housing body is attached to the lead frame. For better adhesion of the housing body to the lead frame, the lead frame may comprise anchor structures formed by cavities etched isotropically from the rear side and connected to the front side of the lead frame. The potting material fills these cavities and hardens to form the resulting housing body. The etching profile of the anchor structures, which tapers towards the front side, prevents delamination of the housing body. Apart from its top side, the circuit chip can be completely enclosed by the housing body. The wire bonds can also be completely enclosed by the housing body. In lateral directions, the housing body is flush with the lead frame, so that a compact housing is formed on the underside of which the contacts of the lead frame are accessible.

The recess or depression of the housing body is located on the top side of the circuit chip, so that at least parts of the redistribution layer and the semiconductor chip arranged thereon are not covered by the housing body. In the transverse direction, the housing body can be flush with the semiconductor chip or protrude beyond it. The fact that the housing body is flush with the semiconductor chip can mean that the semiconductor chip, and in particular the radiation-emitting side of the semiconductor chip, forms a common surface with the housing body. Side walls of the recess can be spaced from or adjacent to the semiconductor chip. If the optoelectronic component comprises a plurality of radiation-emitting semiconductor chips, each semiconductor chip can be arranged in a separate recess, or groups of semiconductor chips can be arranged in a common recess.

Advantageously, the optoelectronic component is protected from mechanical stress and/or environmental influences by the housing body and forms a compact housing together with the lead frame. Furthermore, as explained above, the housing body can comprise reflective/reflecting properties for the emitted light, which increases the light yield. In addition, the recess in the housing body, in which the semiconductor chips are arranged, supports the mixing of the color spectra emitted by the semiconductor chips, as light is reflected by the side walls of the recess.

According to at least one further embodiment, side walls of the recess of the housing body are spaced from the at least one radiation-emitting semiconductor chip.

This can mean that a base area of the recess is larger than a base area formed by the at least one semiconductor chip. Reflection properties of the recess can be influenced by side walls spaced from the semiconductor chip. The side walls can be vertical or tilted with respect to the main plane of extension of the lead frame. Directional radiation can be achieved by forming the side walls formed by the recess as inclined reflectors.

According to at least one further embodiment, the optoelectronic component comprises a reflective layer which is arranged in the recess of the housing body. In lateral directions, the reflective layer is adjacent to the at least one radiation-emitting semiconductor chip.

The reflective layer may be arranged in lateral directions between the at least one semiconductor layer and the side walls of the recess. The reflective layer may cover areas of the top side of the circuit chip in the recess that are not covered by the semiconductor chip. The reflective layer can preferably be formed by a white, light reflective/reflecting potting material and can, for example, comprise silicone or epoxy resin. The radiation intensity can be further improved by the reflective layer.

According to at least one alternative embodiment, the side walls of the recess are in direct contact with the at least one radiation-emitting semiconductor chip. The side walls of the recess enclose the at least one radiation-emitting semiconductor chip in lateral directions.

In this embodiment, the base area of the at least one recess is identical to the base area of the at least one semiconductor chip. This means that the housing body is formed by overmolding the circuit chip and the semiconductor chip with a potting material. In the case of a plurality of semiconductor chips, each semiconductor chip can be enclosed by the housing body except for its radiation-emitting surface. Advantageously, no reflective layer is required in this embodiment, which simplifies the manufacturing process and leads to a reduction in costs.

According to at least one further embodiment, the optoelectronic component further comprises an encapsulation. The encapsulation covers the at least one radiation-emitting semiconductor chip in the transverse direction. The encapsulation comprises a material that is transparent to the emitted radiation. Alternatively or additionally, the encapsulation comprises a material that diffusely scatters the emitted radiation.

The encapsulation can be arranged in the recess and cover the semiconductor chip. In this case, the encapsulation can form a common flat surface with the housing body, i.e. the encapsulation fills the recess of the housing body. Alternatively, the encapsulation is arranged on the surface of the housing body and also covers the radiation-emitting side of the semiconductor chip or chips. The encapsulation can be formed by a clear radiation permeable potting material. The potting material forming the encapsulation may contain diffuser particles, i.e. radiation scattering particles, which scatter the radiation hitting them. The encapsulation also serves to protect the at least one semiconductor chip. In addition, the encapsulation improves the light outcoupling due to a suitably selected refractive index. This increases the portion of radiation emitted through the emission surface of the component and thus improves the efficiency of the component. Furthermore, the diffuser particles contained in the encapsulation can contribute to better mixing of the emitted light.

According to at least one further embodiment, the optoelectronic component further comprises a temperature sensor integrated in the circuit chip, which is used to monitor the heat produced by the circuit chip and the semiconductor chip.

Due to the stacked arrangement of the circuit chip with the at least one semiconductor chip, the temperature sensor is located in close proximity to the semiconductor chip. Temperature fluctuations of the semiconductor chip can therefore be determined quickly and reliably by the temperature sensor.

According to one embodiment, a control unit is also integrated in the circuit chip. The control unit is used to control the driver circuit based on the temperature determined by the temperature sensor.

As described above, the brightness of red LEDs in particular is very temperature-sensitive, which means that temperature compensation may be necessary. The control unit is connected to the temperature sensor and receives information on the determined temperature from it. Based on the measured values, the control unit regulates the drive current provided by the driver circuit to operate the semiconductor chip. This can be used, for example, to ensure a constant color point that is independent of the temperature. Alternatively or additionally, the control unit can be provided and configured to vary the brightness of individual LEDs by regulating the driver currents, allowing different light mixing ratios and/or dynamic color gradients to be realized.

According to at least one further embodiment, the optoelectronic component further comprises an adhesion layer between the lead frame and the circuit chip. In one embodiment, the optoelectronic component comprises a further adhesion layer between the circuit chip and the at least one radiation-emitting semiconductor chip. The adhesion layer and/or the further adhesion layer are configured to dissipate the heat produced by the circuit chip and the semiconductor chip to the lead frame.

Furthermore, the adhesive layer and the further adhesive layer are configured to attach the circuit chip to the lead frame or the semiconductor chip to the circuit chip. The adhesive layer and/or the further adhesive layer can be formed by glue layers or underfill layers. The adhesive layer and/or the further adhesive layer can be configured to match the different thermal expansion coefficients (coefficient of thermal expansion, CTE) of the materials used in order to mechanically and thermally stabilize the stacking arrangement of the chips. Furthermore, the adhesive layers allow heat to be quickly dissipated to the lead frame, i.e. the heat sink, so that the temperatures and thus the radiation characteristics of the LEDs can be kept constant.

According to at least one further embodiment, a lighting unit comprises a plurality of optoelectronic components according to one of the above-mentioned embodiments. Furthermore, the lighting unit comprises a control unit, wherein the control unit is provided and configured to control the optoelectronic components individually or in groups via a bus system.

For example, the lighting unit forms a controllable chain of multicolored LEDs with optoelectronic components. Such a chain can be integrated into vehicle interiors, for example, and perform other functions in addition to ambient lighting. For example, the lighting unit can use dynamic and color effects to help draw the driver's attention. The communication between autonomous vehicles and the visual communication between other road users is conceivable.

According to at least one further embodiment, a method of manufacturing an optoelectronic component is disclosed. All features disclosed for the optoelectronic component are also disclosed for the manufacturing method and vice versa.

According to the method, a lead frame with a plurality of contacts is provided. Furthermore, a circuit chip is provided which comprises a bottom side and a top side. The circuit chip comprises a driver circuit. Further, at least one radiation-emitting semiconductor chip is provided.

According to the method, a redistribution layer is arranged on the top side of the circuit chip. The redistribution layer is intended and configured to electrically contact the driver circuit and the at least one radiation-emitting semiconductor chip. The circuit chip is arranged on the lead frame, with the bottom side of the circuit chip facing the lead frame.

Furthermore, the method comprises realizing electrical connections between the redistribution layer and the contacts of the lead frame by means of wire bonds. The at least one radiation-emitting semiconductor chip is arranged on the redistribution layer at the top side of the circuit chip. The electrical connection between the terminals of the radiation-emitting semiconductor chip and the redistribution layer is realized by means of bumps.

By applying an application-specific redistribution layer to the circuit chip contacting surfaces are created for the semiconductor chip. The best possible thermal coupling is achieved by mounting the semiconductor chip directly on the top side of the circuit chip. Compared to a lateral arrangement of the semiconductor chip next to the circuit chip, stacking them requires less lateral space, which results in a significant reduction in component size.

According to at least one further embodiment, the at least one radiation-emitting semiconductor chip is attached to the top side of the circuit chip by means of flip-chip mounting on the redistribution layer.

In particular, this includes all common flip-chip mounting techniques. For example, the connections of the semiconductor chip can be soldered to the redistribution layer using the C4 method (“controlled collapsed chip connection”). Furthermore, in addition to the solder between the chips, an elastic, temperature-resistant plastic (so-called underfill) can be arranged so that the different thermal expansion coefficients of the circuit chip and semiconductor chip do not destroy the structure. It is also possible that the flip-chip mounting is carried out using isotropic conductive adhesive (ICA), anisotropic conductive adhesive (ACA) or non-conductive adhesive (NCA). The electrical terminals of the semiconductor chip are opposite the radiation-emitting side. Flip-chip mounting eliminates the need for wire bonds to the semiconductor chip, which reduces costs.

According to at least one further embodiment, a housing body is formed. The housing body is attached to the lead frame. The housing body is formed by overmolding the circuit chip with a plastic material and comprises at least one recess on the top side of the circuit chip. The at least one radiation-emitting semiconductor chip is placed in the recess of the housing body. Alternatively, the radiation-emitting semiconductor chip is already arranged on the top side of the circuit chip before the housing body is formed, so that the recess in the housing body is created by the semiconductor chip.

The housing body is preferably formed using an injection molding method. This can be a so-called transfer molding, in which the recess of the housing body is formed by a corresponding negative mold, which is removed again after the potting material has hardened. It is also possible that a so-called film-assisted molding (FAM) method is used. As described above, the fixing of the housing body to the lead frame can be supported by anchor structures on the lead frame. Here, cavities are etched into the lead frame before the housing body is molded, with the etching profile tapering from the rear side of the lead frame to the front side of the lead frame. The potting material fills these cavities. The tapered etching profile prevents the potting material from delaminating after curing.

The optoelectronic component is protected from mechanical stress and/or environmental influences by the housing body and forms a compact housing together with the lead frame. Furthermore, the housing body, which is preferably formed by a white material, can comprise reflective/reflecting properties for the emitted light, which increases the light yield. In addition, the recess in the housing body, in which the semiconductor chips are arranged, supports the mixing of the color spectra emitted by the semiconductor chips, as light is reflected by the side walls of the recess.

According to at least one further embodiment, the method comprises the arrangement of a reflective layer. The reflective layer is arranged in the recess of the housing body and adjoins the at least one radiation-emitting semiconductor chip in lateral directions.

For example, the reflective layer is introduced into the recess from above using an injection process. The reflective layer can be formed by a white silicone casting resin that covers the bottom of the recess, i.e. the top side of the circuit chip. The recess can be shaped in such a way that a needle carrying the casting resin can be inserted into the recess and then removed again. The reflective layer is preferably introduced into the recess after the arrangement of the at least one semiconductor chip, so that the reflective layer surrounds the semiconductor chip laterally. The reflective layer reflects the light emitted by the at least one semiconductor chip and thus improves the light yield.

According to at least one further embodiment, the housing body is formed before the arrangement of the radiation-emitting semiconductor chip at the top side of the circuit chip. In this case, the recess of the housing body comprises a base area that is larger than a base area of the at least one radiation-emitting semiconductor chip. The semiconductor chip is inserted into the recess in a subsequent process step.

The recess is formed, for example, by a corresponding negative mold which is pressed onto the top of the circuit chip during the injection molding process (transfer molding). This process sequence makes it possible to achieve that the side walls of the recess are spaced from the at least one semiconductor chip and can represent reflector surfaces for the emitted light.

According to at least one further embodiment, the housing body is molded after the arrangement of the radiation-emitting semiconductor chip on the top side of the circuit chip. Here, the housing body is formed by overmolding the semiconductor chip in lateral directions with the plastic material. In this case, the side walls of the respective recess adjoin the semiconductor chip so that the base area of the recess matches the base area of the semiconductor chip.

In this embodiment, no reflective layer is advantageously required and the at least one semiconductor chip is protected in lateral directions by the housing body. The housing body can preferably be generated using a FAM method.

According to at least one further embodiment, the method further comprises the arrangement of an encapsulation. The encapsulation covers the at least one radiation-emitting semiconductor chip in the transverse direction. The encapsulation comprises a material that is transparent and/or diffusely scattering for the emitted radiation of the semiconductor chip.

The encapsulation can be formed by a clear potting material that is injected into the recess of the housing body. Alternatively, the encapsulation is a layer that is applied over the entire surface or over the flat surface of the housing body. In either case, the encapsulation covers the at least one semiconductor chip in the transverse direction. The encapsulation serves to protect the semiconductor chip. In addition, the encapsulation improves the light outcoupling due to a suitably selected refractive index.

Further embodiments of the method of manufacturing an optoelectronic component will be apparent to the skilled reader from the embodiments of the optoelectronic component described above.

The preceding and following description relates equally to the optoelectronic component, the lighting unit, and the method of manufacturing an optoelectronic component.

Further advantages, advantageous embodiments and further developments result from the embodiments described below in conjunction with the figures.

### BRIEF DESCRIPTION OF THE DRAWINGS

In the embodiments and figures, identical, similar or similarly acting elements may each be provided with the same reference signs. The elements shown and their relative sizes are not to be regarded as true to scale; rather, individual elements, such as layers, components, structural elements and areas, may be shown in exaggerated size for better visualization and/or better understanding.

FIG. 1 shows a schematic representation of an optoelectronic component according to an embodiment;

FIG. 2 shows a schematic representation of a detail of the optoelectronic component according to an embodiment;

FIGS. 3a and 3b show schematic representations of various arrangement options for an optoelectronic component according to further embodiments;

FIG. 4 shows a schematic representation of a lighting unit according to a further embodiment;

FIGS. 5a to 5h show a method for manufacturing an optoelectronic component according to an embodiment; and

FIGS. 6a to 6d show a method for manufacturing an optoelectronic component according to a further embodiment.

### DETAILED DESCRIPTION OF ILLUSTRATIVE EMBODIMENTS

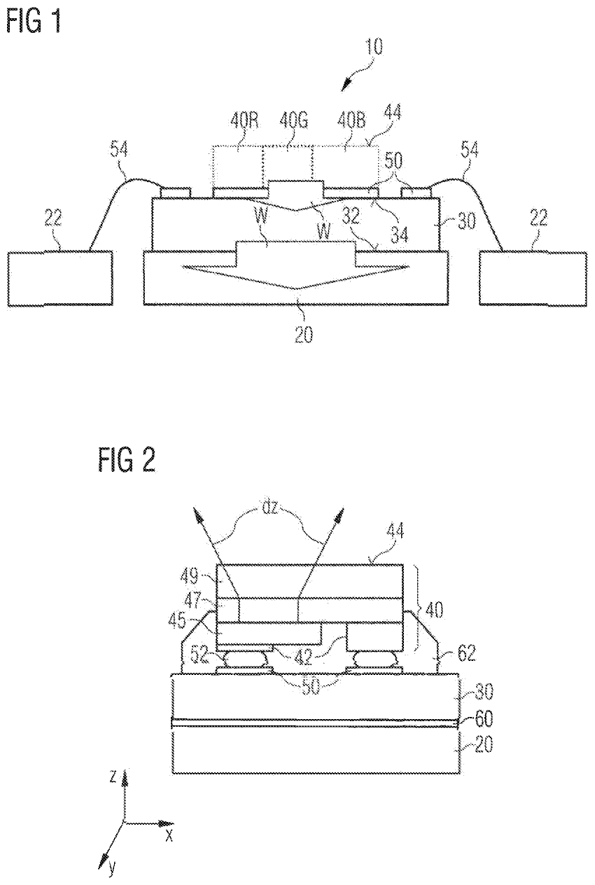

In conjunction with FIG. 1, an embodiment of an optoelectronic component 10 is shown, which is used to illustrate the arrangement concept.

The optoelectronic component 10 comprises a lead frame 20 with a plurality of contacts 22. The lead frame 20 comprises a base body around which the contacts 22 are arranged in lateral directions x, y. Lateral directions run parallel to a main plane of extension of the lead frame 20. A circuit chip 30 is arranged on or above the base body of the lead frame 20. The circuit chip comprises a bottom 32 which faces the lead frame 20. A top side 34 of the circuit chip 30 is facing away from the lead frame 20. A driver circuit 36 (not shown) is integrated in the circuit chip 30.

At least one radiation-emitting semiconductor chip 40 is arranged on or above the circuit chip 30, i.e. on its top side 34. In the example shown, the at least one radiation-emitting semiconductor chip 40 comprises a first semiconductor chip 40R which, in operation, emits light in the red wavelength range. In addition, the at least one radiation-emitting semiconductor chip 40 comprises second and third semiconductor chips 40G, 40B, which emit light in the green and blue wavelength ranges, respectively, during operation. In a preferred embodiment, the semiconductor chips 40 each comprise a light-emitting diode (LED). An emission direction dz (not shown) of the semiconductor chips 40 essentially comprises directions that are directed away from the lead frame 20. In particular, this includes a transverse direction z that is perpendicular to a main plane of extension of the lead frame 20. This may mean that a radiation-emitting side 44 of the semiconductor chips 40 is facing away from the circuit chip 30. A base area of the semiconductor chips 40 is smaller than a base area of the circuit chip 30.

A redistribution layer 50 is arranged between the circuit chip 30 and the at least one radiation-emitting semiconductor chip 40. The redistribution layer 50 is provided and configured to electrically contact the driver circuit 36 and the radiation-emitting semiconductor chips 40. The redistribution layer 50 is arranged on the top side 34 of the circuit chip 30 and is electrically connected to components of the circuit chip 30 (e.g. via conductor tracks and vias integrated in the circuit chip 30). The redistribution layer 50 is structured and forms areas insulated from each other. The semiconductor chips 40 are arranged on parts of the redistribution layer 50.

Connections 42 (shown in FIG. 2) of the radiation-emitting semiconductor chips 40 are electrically connected to the redistribution layer 50 via bumps 52 (shown in FIG. 2). In particular, this can mean that the semiconductor chips 40 are attached to the redistribution layer 50 by means of flip-chip mounting. The terminals 42 of the semiconductor chips 40 are arranged on the side of the semiconductor chips 40 opposite the radiation-emitting side 44. In particular, the terminals 42 may include an anode terminal and a cathode terminal for the LED integrated in the semiconductor chip. Further parts of the redistribution layer 50 are electrically connected to the contacts 22 of the lead frame 20 via wire bonds 54. The wire bonds can be, for example, gold wires that are attached by a wire bonding process.

FIG. 1 also schematically shows a heat flow in the optoelectronic component. The heat W produced by the semiconductor chips 40 is dissipated to the lead frame 20 via the circuit chip 30. Similarly, the heat W produced by the circuit chip 30 is dissipated to the lead frame 20. The lead frame can therefore serve as a heat sink. The circuit chip 30 and the semiconductor chips 40 are in thermal contact with each other. A temperature sensor 38 (not shown) integrated in the circuit chip 30 can therefore reliably measure the temperature in the semiconductor chips 40.

FIG. 2 shows the structure of a further embodiment in greater detail. As can be seen, the circuit chip 30 is attached to the lead frame 20, or to the base body of the lead frame 20, by means of an adhesive layer 60. The adhesive layer 60 is thus located between the lead frame 20 and the circuit chip 30. The adhesive layer 60 is also configured to dissipate the heat W produced by the circuit chip 30 and the semiconductor chip 40 to the lead frame 20.

FIG. 2 also shows the parts of the redistribution layer 50 that are connected to the terminals 42 of the semiconductor chip 40. The terminals 42 of the semiconductor chip 40 are connected to the redistribution layer 50 by means of bumps 52. For example, the bumps 52 are designed as “solder bumps” or “stud bumps”. The bumps 52 are arranged between the redistribution layer 50 and the terminals 42 of the semiconductor chip 40.

In the embodiment according to FIG. 2, the semiconductor chip 40 comprises a substrate 49. The substrate 49 is used, for example, for the epitaxial growth of semiconductor layers 45, 47. As mentioned above, the semiconductor chip 40 is preferably arranged on the circuit chip 30 by means of flip-chip mounting. This means that the substrate 49 forms the top layer of the semiconductor chip 40 in the finished product. The substrate 49 forms the radiation-emitting side 44 of the semiconductor chip 40. For example, the substrate 49 is a sapphire substrate. Furthermore, the semiconductor chip 40 comprises a first semiconductor layer 45 and a second semiconductor layer 47. The second semiconductor layer 47 is arranged between the first semiconductor layer 45 and the substrate 49. The first and second semiconductor layers 45, 47 may be GaN layers that are epitaxially grown on the substrate 49. The first semiconductor layer 45 may be p-doped, while the second semiconductor layer 47 may be n-doped, or vice versa. The first semiconductor layer 45 forms a pn junction with the second semiconductor layer 47. A first terminal 42, which is electrically connected to the p-doped semiconductor layer, forms an anode terminal. A second terminal 42, which is connected to the n-doped semiconductor layer, forms a cathode terminal.

A further adhesive layer 62 is arranged between the circuit chip 30 and the semiconductor chip 40, which is formed, for example, by an elastic, temperature-resistant plastic (so-called underfill) or an adhesive layer. The connections 42 and the bumps 52 are embedded in the further adhesive layer 62. The further adhesive layer 62 is used for adhesion between the circuit chip 30 and the semiconductor chip 40, as well as for efficient heat transport from the semiconductor chip 40 to the lead frame 20. The further adhesive layer 62 can also equalize the thermal expansion coefficients.

FIG. 2 also shows the radiation direction dz of the at least one radiation-emitting semiconductor chip 40, which includes the transverse direction z. This means that light is essentially emitted away from the lead frame 20.

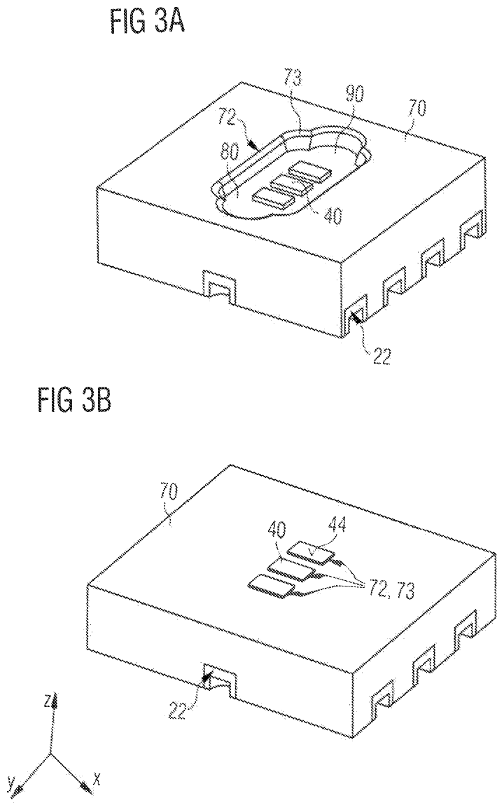

FIG. 3a shows the optoelectronic component 10 according to a further embodiment. The optoelectronic component 10 according to FIG. 3a further comprises a housing body 70, which is attached to the lead frame 20 and encloses the circuit chip 30 (not shown, as it is concealed). The housing body 70 also at least partially encloses the lead frame 20 in lateral directions x, y, whereby the contacts 22 of the lead frame 20 remain accessible. As shown, the contacts 22 may comprise inspection structures to allow visual inspection when soldering the contacts. The housing body 70 closes in lateral directions x, y with the lead frame 20, so that a compact housing is formed whose connections (contacts 22) do not protrude beyond the housing. This means that the housing can be implemented as a QFN (quad flat no leads) chip housing, for example.

The housing body 70 encloses the circuit chip 30 and the wire bonds 54. On the top side 34 of the circuit chip 30, the housing body 70 comprises a recess 72. The recess 72 may also be referred to as a cavity or depression. In the area of the recess 72, the housing body 70 does not enclose or cover the circuit chip 30. This means that at least parts of the top side 34 of the circuit chip 30 are free of the housing body. The at least one radiation-emitting semiconductor chip 40 is arranged in the recess 72. As shown, a first, second and third semiconductor chip 40R, 40G, 40B may be arranged in a common recess 72. The shape of the recess 72 can be arbitrary. Side walls 73 of the recess 72 are spaced from the semiconductor chips 40 as shown in FIG. 3a. The side walls may be parallel or tilted with respect to the transverse direction z. The shape of the recess 72 and the tilting of the side walls 73 can be selected such that emitted light is reflected by the side walls 73 of the recess 72. A reflective layer 80 may be arranged at the bottom of the recess, i.e. on the top side 34 of the circuit chip 30, which laterally surrounds the semiconductor chips. The reflective layer 80 can be adjacent to the semiconductor chips 40 in lateral directions x, y. Furthermore, according to FIG. 3a, an encapsulation 90 can be arranged in the recess, which covers the semiconductor chips 40 in transverse direction z. The encapsulation may comprise a material that is transparent and/or diffusely scattering for the emitted radiation. The encapsulation 90 can fill the recess and form a common flat surface with the housing body 70.

FIG. 3b illustrates an optoelectronic component 10 according to an alternative embodiment. In the example shown, the side walls 73 of the recess 72 are in direct contact with the semiconductor chips 40, which means that the housing body 70 encloses the semiconductor chips 40 in lateral directions x, y. The semiconductor chips 40 are arranged in a row and spaced apart from each other. Each of the semiconductor chips 40 is arranged in its own recess 72. The radiation-emitting sides 44 of the semiconductor chips 40 form a common flat surface with the housing body 70, i.e. unlike in FIG. 3a, the housing body 70 does not protrude beyond the semiconductor chips 40.

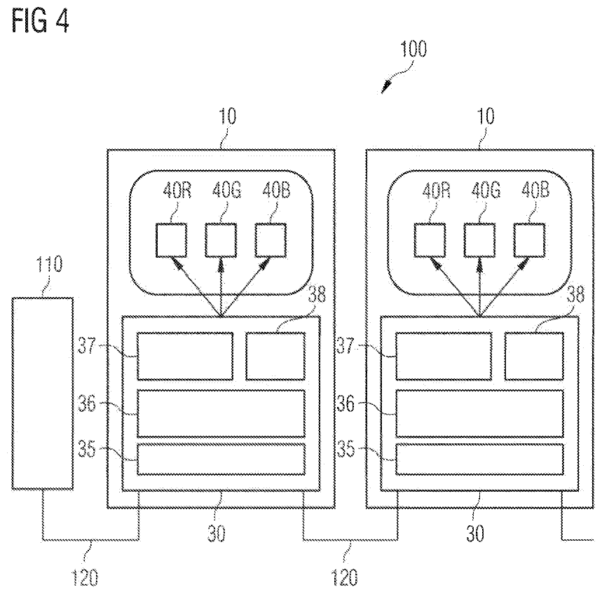

A lighting unit 100 is shown schematically in FIG. 4. The lighting unit 100 comprises a plurality of optoelectronic components 10. In FIG. 4, two optoelectronic components 10 arranged in series can be seen, but more components 10 are also possible, as indicated. As in the previous figures, the optoelectronic components 10 comprise a circuit chip 30 and at least one semiconductor chip 40 (or 40R, 40G, 40B). In addition to the driver circuit 36, the circuit chip 30 also comprises a communication unit 35, a control unit 37 and a temperature sensor 38. The lighting unit 100 also comprises a control unit 110. The control unit 110 is connected to the optoelectronic components 10 via a bus system 120. As indicated, the optoelectronic components 10 and the control unit 110 may be interconnected in series by means of a master-slave arrangement. The control unit 110 can be provided and configured to send commands via the bus system 120 to the communication units 35 and thus control the optoelectronic components 10 individually or in groups. The control of the semiconductor chips 40 via the driver circuit 36 with corresponding drive currents is illustrated by means of arrows. The driver circuit 36 can be controlled via the control unit 37, which processes the temperature measured by the temperature sensor 38 in order to compensate for a corresponding temperature drift.

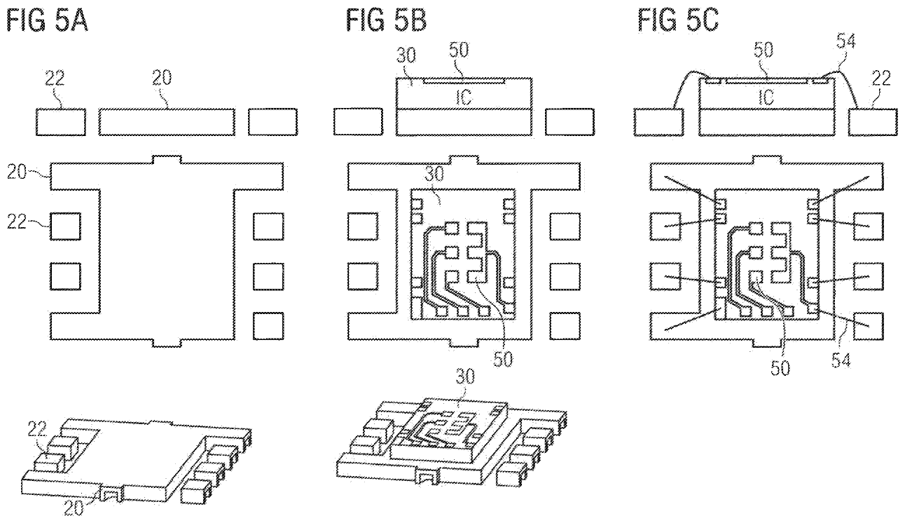

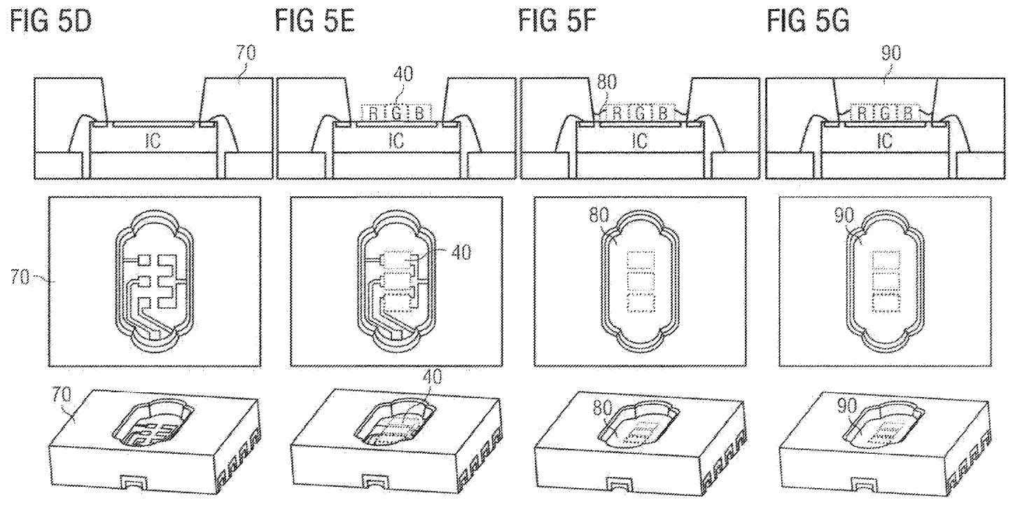

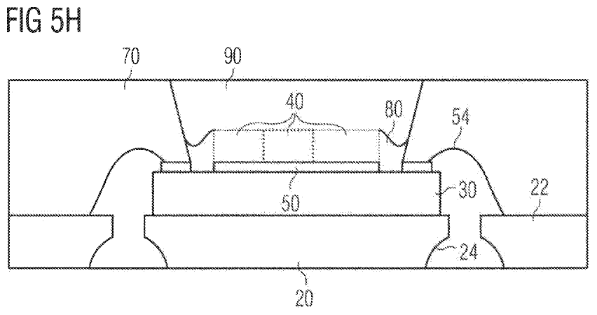

FIGS. 5a to 5g illustrate an example of a manufacturing process for an optoelectronic component 10. The figures each show a cross-section, a top view and an oblique view of the individual process steps. A cross-section of the finished component 10 is shown enlarged in FIG. 5h.

The method begins (FIG. 5a) with the provision of a lead frame 20. The lead frame 20 comprises a base body around which the contacts 22 are arranged laterally.

In a next step according to FIG. 5b, the circuit chip 30 is arranged on the lead frame 20. A redistribution layer 50 is arranged on the top side 34 of the circuit chip 30 facing away from the lead frame 20. The redistribution layer 50 comprises a plurality of contact areas and conductor tracks.

In a next step according to FIG. 5c, a part of the contact areas of the redistribution layer 50 is connected to the contacts 22 of the lead frame 20 by means of wire bonds 54.

FIG. 5d shows the forming of the housing body 70. The housing body 70 is attached to the lead frame 20 and is laterally flush with it. The circuit chip 30 including the wire bonds 54 are embedded in the housing body 70, whereby a part of the top side of the circuit chip 30 remains uncovered. In this part, the housing body 70 comprises a recess 72. The housing body 70 projects beyond the circuit chip 30 in the transverse direction z.

After the housing body 70 has been formed, the semiconductor chips 40 are inserted into the recess 72 on the contact areas of the redistribution layer 50 provided (see FIG. 5e). The semiconductor chips 40 (RGB) are connected to the contact areas of the redistribution layer 50 by means of flip-chip mounting. In particular, an anode terminal 42 and a cathode terminal 42 of the respective semiconductor chips 40 are electrically contacted.

In a further process step according to FIG. 5f, the reflective layer 80 is inserted into the recess 72, so that the reflective layer 80 is arranged between the semiconductor chips 40 and the side walls 73 of the housing body 70. The reflective layer 80 covers the regions of the top side 34 of the circuit chip 30 that are still free.

In a final step as shown in FIG. 5g, the encapsulation 90 is inserted into the recess 72. The encapsulation 90 covers the semiconductor chips 40 and the reflective layer 80 and fills the recess 72.

In the finished component 10 according to FIG. 5h, the anchor structures 24 in the lead frame 20 can also be seen. The anchor structures 24 are formed by cavities extending from the rear side to the front side, the profile of which tapers towards the front side. This prevents the cured housing body 70 from detaching from the lead frame 20.

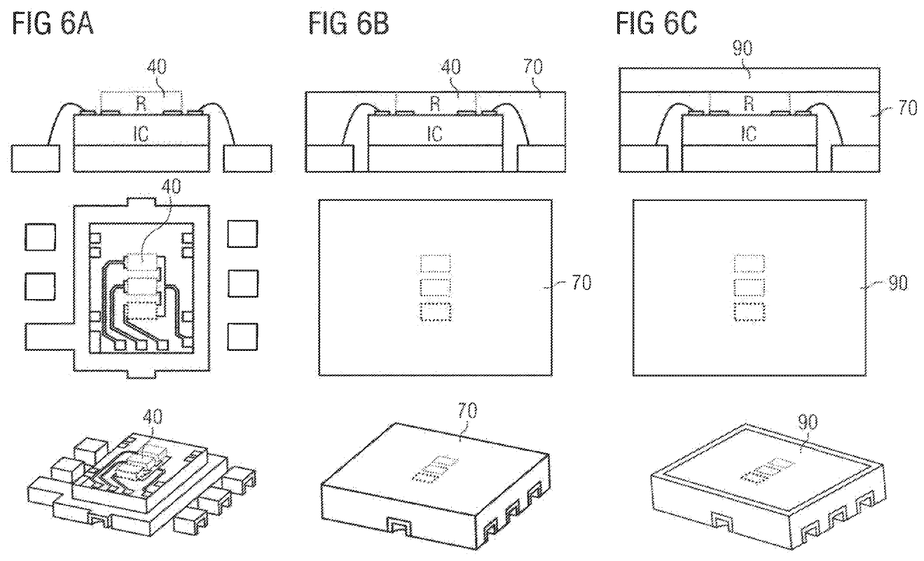

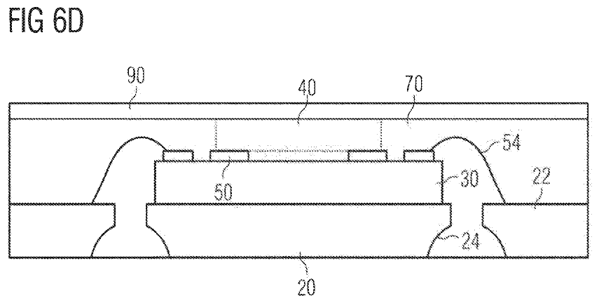

FIGS. 6a to 6d show an alternative process that follows on from the process step shown in FIG. 5c.

According to FIG. 6a, the at least one semiconductor chip 40 is placed on the top side 34 of the circuit chip 30 and connected to the redistribution layer 50 before the housing body 70 is formed.

In a subsequent process step according to FIG. 6b, the housing body 70 is formed in such a way that it encloses the stack consisting of circuit chip 30 and semiconductor chip 40 in lateral directions x, y and closes laterally with the lead frame 20. The housing body 70 can form a common flat surface with the radiation-emitting semiconductor chip 40, i.e. it is flush with it in the transverse direction z.

In a final (optional) process step according to FIG. 6c, the encapsulation 90 is arranged on the surface of the housing body 70 so that it covers at least the radiation-emitting side 44 of the semiconductor chip 40.

FIG. 6d shows an enlarged cross-section of the resulting component 10.

The features and embodiments described in connection with the figures can be combined with one another according to further embodiments, even if not all combinations are explicitly described. Furthermore, the embodiments described in connection with the figures may alternatively or additionally comprise further features as described in the general part.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

1.-17. (canceled)

18. An optoelectronic component comprising:
a lead frame with a plurality of contacts;
a circuit chip comprising a driver circuit and having a bottom side facing the lead frame and a top side facing away from the lead frame;
at least one radiation-emitting semiconductor chip arranged on the top side of the circuit chip;
a redistribution layer arranged between the circuit chip and the radiation-emitting semiconductor chip for electrically contacting the driver circuit and the radiation-emitting semiconductor chip; and
a housing body fastened to the lead frame, the housing body enclosing the circuit chip and having at least one recess above the circuit chip, in which the at least one radiation-emitting semiconductor chip is arranged,
wherein terminals of the radiation-emitting semiconductor chip are electrically connected to the redistribution layer via bumps, and
wherein the redistribution layer is electrically connected to the contacts of the lead frame via wire bonds.

19. The optoelectronic component according to claim 18, wherein the at least one radiation-emitting semiconductor chip comprises a light-emitting diode.

20. The optoelectronic component according to claim 18, wherein the at least one radiation-emitting semiconductor chip comprises:
a first semiconductor chip which configured to emit light in a red wavelength range, and/or
a second semiconductor chip configured to emit light in a green wavelength range, and/or
a third semiconductor chip configured to emit light in a blue wavelength range.

21. The optoelectronic component according to claim 18, wherein a radiation direction of the at least one radiation-emitting semiconductor chip comprises a transverse direction perpendicular to a main plane of extension of the lead frame.

22. The optoelectronic component according to claim 18, wherein sidewalls of the recess of the housing body are spaced from the at least one radiation-emitting semiconductor chip.

23. The optoelectronic component according to claim 18, further comprising a reflective layer arranged in the recess of the housing body and adjoining the at least one radiation-emitting semiconductor chip in lateral directions.

24. The optoelectronic component according to claim 18, wherein sidewalls of the recess of the housing body are in direct contact with the at least one radiation-emitting semiconductor chip and enclose it in lateral directions.

25. The optoelectronic component according to claim 18, further comprising an encapsulation covering the at least one radiation-emitting semiconductor chip in a transverse direction and comprising a material transparent and/or diffusely scattering for the emitted radiation.

26. The optoelectronic component according to claim 18, further comprising a temperature sensor integrated in the circuit chip configured to monitor a heat produced by the circuit chip and the semiconductor chip, and wherein a control unit, integrated in the circuit chip, is configured to control the driver circuit based on the temperature determined by the temperature sensor.

27. The optoelectronic component according to claim 18, further comprising:
a first adhesive layer between the lead frame and the circuit chip; and
a second adhesive layer between the circuit chip and the at least one radiation-emitting semiconductor chip,
wherein the first adhesive layer and the second adhesive layer are configured to dissipate a heat produced by the circuit chip and the semiconductor chip to the lead frame.

28. A lighting unit comprising:
a control unit; and
a plurality of optoelectronic components according to claim 18, wherein the control unit is provided and configured to control the optoelectronic components individually or in groups via a bus system.

29. A method for manufacturing an optoelectronic component, the method comprising:
providing a lead frame with a plurality of contacts;
providing a circuit chip comprising a driver circuit having a bottom side and a top side;
providing at least one radiation-emitting semiconductor chip;
arranging a redistribution layer on the top side of the circuit chip, wherein the redistribution layer is configured to electrically contact the driver circuit and the radiation-emitting semiconductor chip;
arranging the circuit chip on the lead frame so that the bottom side of the circuit chip faces the lead frame;
providing electrical connections between the redistribution layer and the contacts of the lead frame by wire bonds;
arranging the at least one radiation-emitting semiconductor chip on the redistribution layer at the top side of the circuit chip;
providing electrical connections between terminals of the radiation-emitting semiconductor chip and the redistribution layer by bumps; and
forming a housing body attached to the lead frame, wherein the housing body is formed by overmolding the circuit chip with a plastic material, and wherein the housing body has at least one recess on the top side of the circuit chip, in which the at least one radiation-emitting semiconductor chip is to be arranged.

30. The method according to claim 29, wherein the at least one radiation-emitting semiconductor chip is attached to the top side of the circuit chip by flip-chip mounting on the redistribution layer.

31. The method according to claim 29, further comprising arranging a reflective layer in the recess of the housing body, the reflective layer being adjacent to the at least one radiation-emitting semiconductor chip in lateral directions.

32. The method according to claim 29, wherein the housing body is formed before an arrangement of the radiation-emitting semiconductor chip on the top side of the circuit chip, and wherein the recess of the housing body comprises a base area which is larger than a base area of the at least one radiation-emitting semiconductor chip.

33. The method according to claim 29, wherein the housing body is formed after the arrangement of the radiation-emitting semiconductor chip on the top side of the circuit chip so that the housing body is formed by overmolding the semiconductor chip in lateral directions with the plastic material.

34. The method according to claim 29, further comprising arranging an encapsulation covering the at least one radiation-emitting semiconductor chip in a transverse direction, wherein the encapsulation comprises a material transparent and/or diffusely scattering for the emitted radiation of the semiconductor chip.

35. An optoelectronic component comprising:
a lead frame with a plurality of contacts;
a circuit chip comprising a driver circuit and having a bottom side facing the lead frame and a top side facing away from the lead frame;
at least one radiation-emitting semiconductor chip arranged on the top side of the circuit chip;
a redistribution layer arranged between the circuit chip and the radiation-emitting semiconductor chip for electrically contacting the driver circuit and the radiation-emitting semiconductor chip, wherein the redistribution layer is arranged on the top side of the circuit chip, and the radiation-emitting semiconductor chip is arranged on the redistribution layer; and
a housing body fastened to the lead frame, the housing body enclosing the circuit chip and having at least one recess above the circuit chip, in which the at least one radiation-emitting semiconductor chip is arranged,
wherein terminals of the radiation-emitting semiconductor chip are electrically connected to the redistribution layer via bumps and the redistribution layer is electrically connected to the contacts of the lead frame via wire bonds.
